(19) United States
(12) Patent Application Publication
(10) Pub. No.: US 2014/0299182 A1
(43) Pub. Date: Oct. 9, 2014

(54) METHOD FOR PRODUCING A SOLAR CELL

(71) Applicants: Christine Meyer, Karlsruhe (DE); Tobias Droste, Muehltal (DE); Yvonne Gassenbauer, Seeheim-Jugenheim (DE); Jens Dirk Moschner, Heverlee (DE); Peter Roth, Hanau (DE)

(72) Inventors: Christine Meyer, Karlsruhe (DE); Tobias Droste, Muehltal (DE); Yvonne Gassenbauer, Seeheim-Jugenheim (DE); Jens Dirk Moschner, Heverlee (DE); Peter Roth, Hanau (DE)

(73) Assignee: Schott Solar AG, Mainz (DE)

(21) Appl. No.: 14/112,180

(22) PCT Filed: Apr. 19, 2012
(86) PCT No.: PCT/EP12/57192

§ 371 Date: Jan. 20, 2014

(30) Foreign Application Priority Data
Apr. 19, 2011 (DE) 10 2011 002 174.4

(51) Int. Cl. H01L 31/0224

(52) U.S. Cl. CPC H01L 31/02245
USPC 136/256; 136/252; 438/98

(57) ABSTRACT

A method for producing an MWT-PERC solar cell is provided, in which openings in the substrate of the solar cell have contact passages and emitter regions that are present on the back side of the solar cell are completely removed outside the contact passages and a dielectric layer is applied on the back side, whereby a paste, which does not act in an electrically contacting manner opposite the substrate, is used for the contact passages.

The invention relates to a method for producing a solar cell made of a semiconductor substrate of a first conductivity type, in particular a p- or n-silicon-based semiconductor substrate, which has a front side and a back side, the method comprising at least the steps of:
A) Forming several passage openings extending from the front side to the back side;
B) Producing a layer of a conductivity type that is opposite to the first conductivity type along the front side by diffusing in a dopant from a dopant source;
C) Producing an electrically conducting connection between the front side through the passage opening to the contact regions adjacent to the passage openings on the back side.

The subject of the invention is a method for producing a solar cell composed of a semiconductor substrate of a first conductivity type, in particular a p- or n-doped monocrystalline or multicrystalline silicon substrate, which produces a good isolation in the passage aperture for EWT (emitter wrap through), MWT (metal wrap through) as well as the combination of MWT and PERC (passivated emitter and rear cell) designs.

The efficiency of a solar cell, among other things, depends on the front surface which is uncovered to the incident radiation. Since the contacts on the front side, however, limit the effective surface, back-side contact cells have been developed, which are known as metal wrap through(MWT) cells and emitter wrap through(EWT) cells. In these cells, the layer of the opposite conductivity type on the front side, i.e., for a solar cell with a p-doped substrate, the n-doped emitter (EWT) and/or a metal connection to this emitter (MWT) is guided through the passage openings running from the front side to the back side, in order to then make possible a contacting on the back side. Here, for MWT cells, a metallizing is additionally introduced on the front side, so that the number of required passage openings is clearly smaller. On the back side, the emitter contacts are then electrically separated from the contacts to the base, in order to avoid short circuits. Without this separation, in the case of standard MWT cells, due to the emitter on the back side, a short circuit may form, which can be eliminated by means of a laser trench or by local back-etching. Ideally, the emitter should be present only on the front side, within the apertures and around the respective contact passage opening on the back side, in order to avoid a short circuit between emitter contact (including contact passage) and base. In the case of MWT-PERC cells, which are covered with an isolation layer on the back side in the region of the emitter contact, there is no need for back-side emitter regions around the contact passage openings. In the case of EWT cells, in principle, metallizing is not required in the passage apertures. For practical reasons of better conductivity, of course, a partial or complete metallizing of the passage apertures is frequently undertaken. The invention is also applicable to this design of an EWT cell, in which a selective electrical contacting of the emitter, but not the base, is necessary.

In the case of MWT cells, a short circuit may arise, in particular, due to the direct contact between the emitter contact and the base, which can form both on the back side as well as inside the contact passage opening. In the case of MWT-PERC cells, this short circuit can be prevented by the insertion of a passivating layer on the back side as well as on the inside of the contact passages as isolation between base material and emitter contact (WO-A-2009/071561).

Conventional manufacturing methods (e.g., Dross et al. “IMPACT OF REAR SURFACE PASSIVATION ON MWT PERFORMANCES”, pages 1291-1294, 2006 IEEE 4^{th} World Conference on Photovoltaic Energy Conversion, Hilton Waikoloa Village, Waikoloa, Hawaii, May 7-12, 2006; Romijn et al., “ASPIRE: A NEW INDUSTRIAL MWT CELL TECHNOLOGY ENABLING HIGH EFFICIENCIES ON THIN AND LARGE MC-SI WAFERS”, 22nd European Photovoltaic Solar Energy Conference, Sep. 3-7, 2007, Milan, Italy, pages 1043 to 1049; Romijn et al.: An overview of MWT cells and evolution to the ASPIRE concept: A new integrated mc-Si cell and module design for high efficiencies, 23rd European Photovoltaic Solar Energy Conference (see 2007), Sep. 1-5, 2008, Valencia, Spain, pp. 1000-1005; Van den Donker et al.: The Starfire project: Towards in-line mass production of thin high efficiency back-contacted multicrystalline silicon solar cells, 23rd European Photovoltaic Solar Energy Conference, Sep. 1-5, 2008, Valencia, Spain, pp. 1048-1050; Clement et al.: Pilot-line processing of highly efficient MWT silicon solar cells, 25^{th} European Photovoltaic Solar Energy Conference, Sep. 6-10, 2010, Valencia, Spain, pp. 1097-1101) of MWT-PERC solar cells comprise the following method steps, without the need that the following sequence necessarily corresponds to the sequence of steps:
a) Forming several, e.g., 16 passage openings extending from the front side to the back side—also called via openings, or abbreviated as vias, or boreholes or apertures—in a semiconductor substrate (wafer) of a first conductivity type.
b) Texturing of the water, if needed, with removal of damage due to sawing the wafer and/or due to producing the passage openings.
c) Producing a layer of a conductivity type opposite to the first conductivity type by diffusing in a dopant from a dopant source along the front side, e.g., by POCl₃ diffusion or H₃PO₄ application with in-line diffusion. As an alternative dopant source, any solution used for solar cells is conceivable. In particular, a selective emitter may also be used, i.e., an emitter that has a different doping profile in different regions (US-A-2010/243040).
d) Removing the glass layer formed by the diffusion.
e) Removing the back-side emitter also formed on the back side by the dopant of the dopant source in the regions of the back side that will function as the base, and, if needed, on the entire back side. Here, a masking can be used for protecting the front-side emitter and/or for protecting the emitter layer in the vias (passage openings) as well as in the region of the emitter contacts on the back side (WO-A-2010/081505). Alternatively, the back side can be protected even before the diffusion (step c)) by a mask/diffusion barrier, so that the emitter is formed only in defined regions (see, e.g., EP-A-2 068 369, Thaidigsmann-EUPVSEC-2010). The back side can be made smooth (polishing etching) simultaneously or in a separate step.
f) Introducing a passivating layer, i.e., a single layer or a multilayer system, e.g., composed of dielectrics or semiconductors with large band gaps, on the base regions of the back side or on the entire back side. Subsequent opening of this passivating layer in partial regions that serve for the later contacting of the base. The latter may be produced, for example in a laser process or by means of an etching paste. The opening of the passivating layer may also be suppressed, depending on the further processing, in particular for fire-through Al pastes and LFC (laser-fired contacts).
g) Introducing an anti-reflection layer on the front side.
h) Producing metal connections and their connection to the corresponding semiconductor regions. The metal is frequently applied in the form of a screen-printing paste that forms its final conductivity as well as the connection to the semiconductor material by subsequent sintering (high-temperature step). Alternatively, other methods, e.g., thermal/physical or chemical methods for metallizing are also conceivable. Three metallizing regions are distinguished:
h1) Production of an electrically conducting connection through the passage openings (vias) throughout (passage metallizing) up to the contact regions adjacent to the passage openings on the back side. The production of these contact regions to the emitter (emitter contact pads) as well as those of the contact regions to the back side, thus the base side, can be achieved in one step and simultaneously with the production of the passage metallizing, or can also be carried out separately in several steps, e.g., by screen printing. Often, the passage openings are filled from the back side, whereby metal regions can be applied simultaneously as emitter and base contact pads.
h2) Production of a front-side contact running along the front side and connection of this contact to the passage metallizing.
h3) Production of a conductive layer running along the back side. This layer is usually contacted to the base locally in the regions in which the passivating layer has an opening to the base. This can be accomplished by applying a non-fire-through paste onto parts of the back side or onto the entire back side, which then produces a contact in the previously opened regions of the passivating layer (Dross 2006). Alternatively, a fire-through paste can be applied onto the regions at which a contact will be formed (Romijn 2007). Or the material will be applied onto the entire back side or parts of the back side and the local contacts will be produced with the help of LFCs (laser-fired contacts) (Clement 2010).
i) Sintering the metal contacts in one or more steps, if needed, at different temperatures. In this way, a local field on the back side, the so-called BSF (back surface field) is formed, in particular, in the opened regions of the passivating layer on the back side.

The steps e) and f) are omitted for a standard MWT cell. In step h3), the contact to the base is formed over the entire surface with the restriction of the emitter contact pads, and, if needed, also the base contact pads. In the sintering, a back surface field is formed correspondingly, not only locally, but over most of the surface of the back side. Since the back-side emitter in the region of the contact pads is not removed or isolated from the base by a dielectric, there is additionally produced a separation of the emitter region on the back side around the contact pads, e.g., by means of a laser. In the remaining region of the back side, the emitter layer which is present is over-compensated by the conductive layer, such as the Al layer, which is applied on the entire surface.

Methods for producing MWT solar cells can be taken from US-A-2010/70243040 or WO-A-2010/081505.

The necessity for structuring the emitter on the back side, for example, by selective formation or removal is mentioned in several publications. In this case, in order to be able to utilize the passivating effect of the dielectric layer, it is necessary that first a layer of the opposite conductivity type that may be present on the back side, thus the n-doped emitter layer in the case of a p-silicon-based wafer, is removed. With chemical back-etching of the emitter on the back side, however, the problem occurs that the etching medium enters into the apertures. Thus, it is not excluded that the emitter is etched away in regions in the aperture, with the consequence that the efficiency of the cell is negatively influenced. Due to the complete or partial removal of the emitter on the back side and/or in the aperture, the risk of a short circuit exists, since the via metallizing might contact the base due to the incomplete emitter.

In the case of passage openings for MWT cells, it is proposed to use an etch-resistant filling prior to the etching step. The emitter on the upper side of the wafer, on walls of the passage openings—also called borehole walls—and in a small area around the borehole (passage opening) on the underside (surface of the n-contact) is thus protected from the etching attack.

The introduction of the filling and its removal after the etching signify an additional expenditure in the production sequence. Precise, defined emitter regions, also on the back side, are necessary for this cell structure.

In order not to necessitate the removal of an emitter on the back side, its formation can be locally prevented or prevented on the entire back side. This can be achieved, e.g., with the help of a diffusion barrier.

Another method for producing defined emitter regions is the introduction of a barrier layer even prior to the diffusion (EP-A-2 068 369).

Insofar as an isolation of the passage openings by means of a dielectric will be used in order to avoid short circuits, the following disadvantages result. The dielectric must be introduced on the entire inside of the aperture in sufficient thickness. With deposition from the gas phase, typically the inlet side is more thickly coated and the thickness decreases in the passage opening going forward the other side. A high material consumption results therefrom in order to obtain the necessary isolating thickness even on the thinnest places. Additionally, the process can only be poorly controlled.

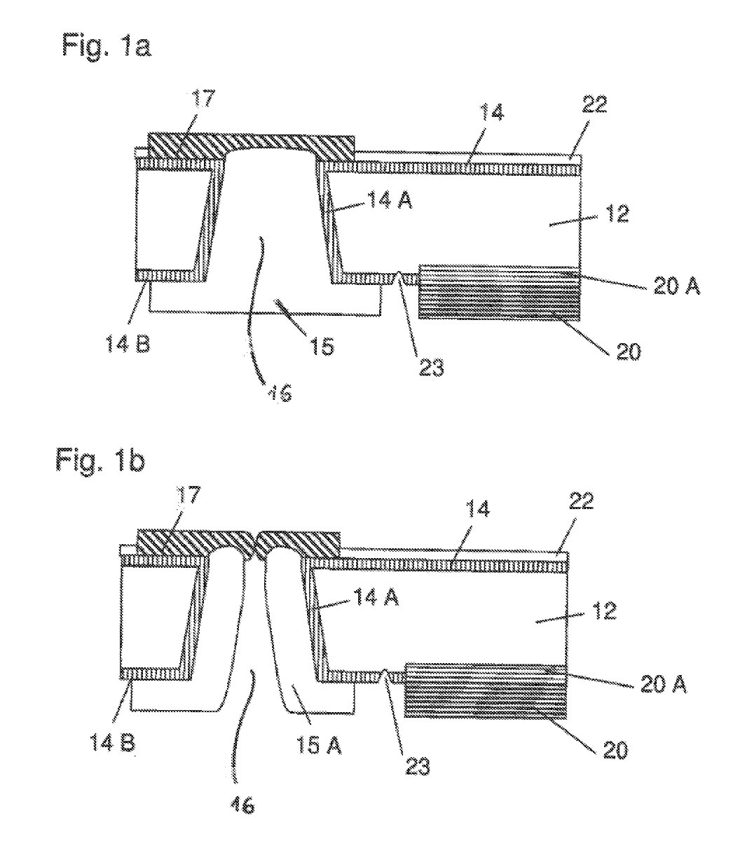

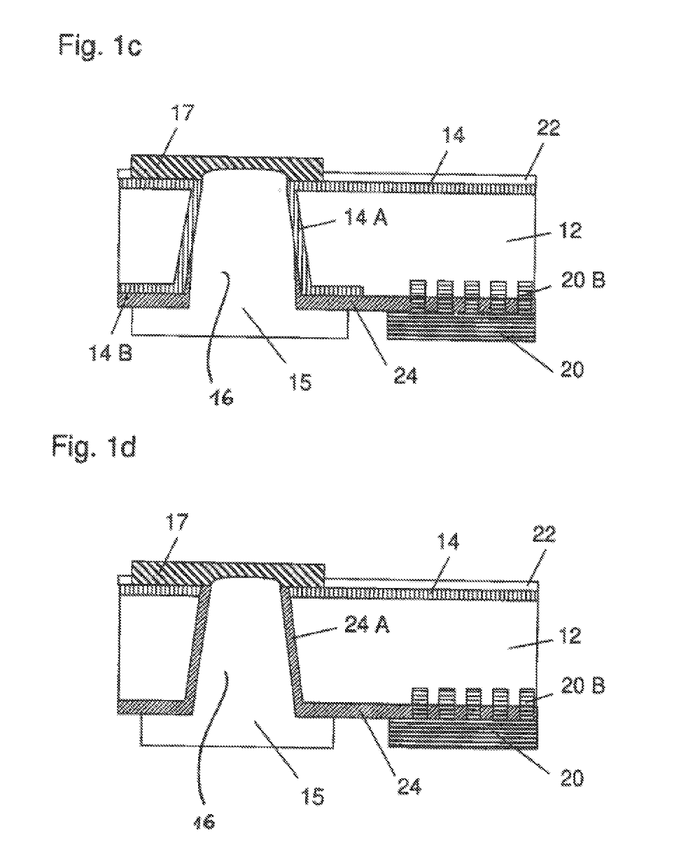

Excerpts of MWT cells according to the prior art can be seen in FIGS. 1a to 1d, wherein the PERC technology is applied in the examples of embodiment of FIGS. 1c and 1d.

The MWT cells shown in the excerpt have a p-silicon-based wafer that forms a base 12 in the example of embodiment. After forming passage openings 16 and after texturing and optional polishing etching of the back side of the wafer, an emitter layer 14 is typically formed on the front side by means of a phosphorus dopant source, the emitter layer also forming in the previously formed passage openings 16 as well as on the back side. The region in the passage openings 16 is characterized by reference 14A. The emitter region 14B present on the back side of the wafer in the region around the passage openings 16 is used for protection from short circuits to the base 12. In the case of a PERC cell (FIGS. 1c, 1d), the emitter running along the back side of the wafer is removed. The phosphosilicate glass (PSG) formed during the emitter manufacture is also removed. For the MWT-PERC cell, a dielectric 24 is then applied to the back side of the wafer, which can partially also extend parasitically into the passage openings 16. Before or after applying the dielectric onto the back side, an anti-reflection layer such as a silicon nitride layer 22 is deposited on the front side of the wafer. Additionally, a cleaning step can be conducted. Subsequently, an electrically conducting material can be introduced into the passage openings 16 down to the back side of the substrate, whereby solder pads are simultaneously applied onto the back side. Then, for MWT cells, the front-side metallizing 17, which in turn contacts the emitter 14 on the front side, is connected on the front side to the metallizing which passes through the passage openings 16 and which can be introduced in the form of a paste. In EWT cells, the passage metallizing, i.e., the metallizing present in the passage openings directly contacts the emitter 14 without the presence of a front-side metallizing. Subsequently, on the back side, but electrically isolated from the electrically conducting contact passages that pass through the passage openings 16, the back side is provided with an electrically conducting layer such as a back-side aluminum layer, whereby a back surface field (region 20B) is formed in previously opened regions of the dielectric in the case of a PERC cell by means of a subsequent sintering process. In the case of an MWT cell (FIGS. 1a, 1b) without PERC technology, the back surface field extends over the entire surface of the applied back-side metallizing 20. The corresponding back surface field is characterized by reference 20A. The penetration of Al into the Si substrate over-compensates the back-side emitter. The back-side metallizing 20 is omitted in the region of the connection contacts for the passage metallizings, e.g., by a masking technique or screen printing. In order to prevent a short circuit between the emitter region 14B running on the back side and back-side metallizing 20, an isolation (region 23) is produced, e.g., by laser or by wet-chemical means.

In the case of EWT cells a special metallizing is not present on the front side. Rather, a direct contacting is produced between the contacts passing through the passage openings 16 and the emitter region running on the front side.

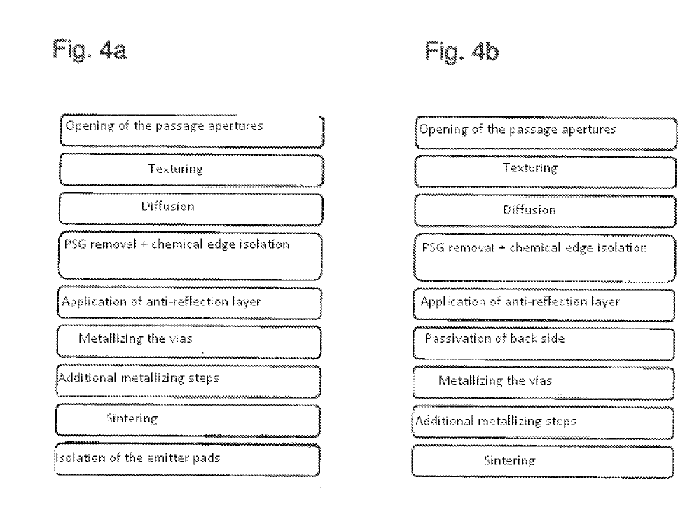

The method steps described above are conventional in the production of solar cells with back-side contacts, whereby the sequence of individual method steps can be interchanged. A typical method procedure can be derived from FIG. 4a.

Since an emitter in the contact passage openings prevents the contact between the passage metallizing and the base 12, it is basically not necessary that the emitter layer formed in the passage openings 16 is removed. In the case of chemical etching away of the emitter layer on the back side, however, the problem arises that the etching fluid enters into the passage openings 16, so that the emitter layer 14A in the aperture is partially etched away.

It is known from the not previously published WO-A-2012/026812 to fill the passage openings of an MWT cell with a plug having an electrical conductivity that decreases from the central region to the walls of the passage opening.

The object of the present invention is based on providing a method for producing a back-side contact solar cell in which it is assured with simple production technology and cost-favorable measures that the contact passage between front-side metallizing and the back side of the solar cell; i.e., the electrically conducting connection to the emitter, does not contact the base.

In particular, a simple MWT or MWT-PERC cell structure, for which precisely defined emitter regions on the back side and the inside of the aperture are not necessary, as well as a correspondingly simple method for the production thereof are provided. Masking and structuring steps shall be omitted.

For the solution of one aspect, the invention essentially provides that a method for producing a solar cell made of a semiconductor substrate, which has a front side and a back side, of a first conductivity type, in particular, a p- or n-silicon-based semiconductor substrate comprising at least the method steps of
A) Forming several passage openings extending from the front side to the back side;
B) Producing a layer of a conductivity type that is opposite to the first conductivity type at least along the front side, e.g. by diffusing in a dopant from a dopant source;
C) Producing an electrically conducting connection between the front side through the passage opening to the back side.
   is hereby characterized in that
D) for producing the electrically conducting connection according to method step C), a material that forms isolating properties opposite the semiconductor substrate (base) in the region of the first conductivity type is used.

In particular, the invention relates to a method for producing an MWT-PERC solar cell, in which openings in the substrate of the solar cell have contact passages, and emitter regions that are present outside of the contact passage and are formed by diffusion onto the back side of the solar cell are completely removed, and a dielectric layer is applied onto the back side, and is characterized in that a paste, which does not act in an electrically contacting manner opposite the walls of the openings, is used for the contact passage.

According to the invention, an isolation is produced in the passage openings, which is not based on the emitter formation inside the passage openings and in the back-side emitter contact regions, but rather on the fact that the metallizing in the passage opening forms a poor or non-conducting contact to the substrate during the sintering, so that one can speak of a non-contacting paste. In particular, this material involves a paste, which forms the necessary dielectric properties in the contact region to the substrate. In MWT-PERC cells, in addition, any necessity of coating the passage opening with a dielectric does not apply.

The invention is particularly characterized in that a paste that contains glass particles, silver particles and organic substances is used as the material passing through the passage openings.

In this case it is particularly provided that a paste is used in which up to 80% to 100% of the silver particles are composed of flakes which have a D90 size distribution determined by laser diffraction in the range of 1 μm to 20 μm, preferably in the range of 2 μm to 15 μm, and particularly in the range between 5 μm and 12 μm.

Most preferably, the invention proposes that a paste is used in which the glass particles have a D90 size distribution determined by laser diffraction in the range of 0.5 pm to 20 μm, preferably in the range between 1 μm and 10 μm, particularly in the range between 3 μm and 8 μm.

It is proposed in an enhancement that a glass is used for the glass particles, which is lead-free and has a glass softening point in the range between 350° C. and 550° C., in particular in the range between 400° C. and 500° C.

In addition, the invention provides that a paste having a solids fraction in the range between 80 wt. % and 95 wt. %, preferably in the range between 84 wt. % and 90 wt. %, is used.

It is also highlighted that a paste is used, the glass fraction of which lies in the range between 1 wt. % and 15 wt. %, preferably in the range region between 4 wt. % and 12 wt. %, in particular in the range between 8 wt. % and 10 wt. %. With respect to silver particles that have the form of flakes, it should be noted that scale-like or plate-like geometries are to be understood by this.

In this case, the paste can be introduced from the back side into the passage openings. As soon as the electrically conducting material that has the isolating properties relative to the semiconductor substrate is introduced and is hardened by thermal treatment—as in a typical sintering process—the front-side metallizing and the back-side aluminum layer are formed in the usual way, whereby, as mentioned, the sequence of the method steps for producing the front-side metallizing and the back-side contact need not absolutely be pre-determined according the previously indicated sequence. In the subsequent thermal treatment—as in a typical sintering process—the isolating paste is also hardened.

There also exists the possibility of removing the back-side emitter without mask. The danger of short circuit to the base arising first upon removal of the back-side emitter and of the emitter in the aperture is prevented by the isolating paste.

In contrast to the isolation with a dielectric, a complete coating of the entire inside of the aperture with the dielectric applied on the back side is not necessary here. This is particularly of advantage in the case of small aperture diameters or large aspect ratios (wafer thickness/aperture diameter).

In particular, the paste is hardened/sintered over a time between 1 sec and 20 sec at a wafer temperature T of ≧700°, in particular 750° C.≦T≦850° C. in a nitrogen atmosphere or an atmosphere composed of nitrogen and up to 40% oxygen.

The teaching according to the invention applies, of course, not only to MWT cells or MWT-PERC cells, but also to EWT cells, without needing further explanation.

Other details, advantages and features of the invention result not only from the claims, and from the features to be derived from the claims—taken alone or in combination—but also from the following description of examples of embodiment to be taken from the drawing.

Herein:

FIGS. 1a -1d show excerpts of MWT solar cells according to the prior art;

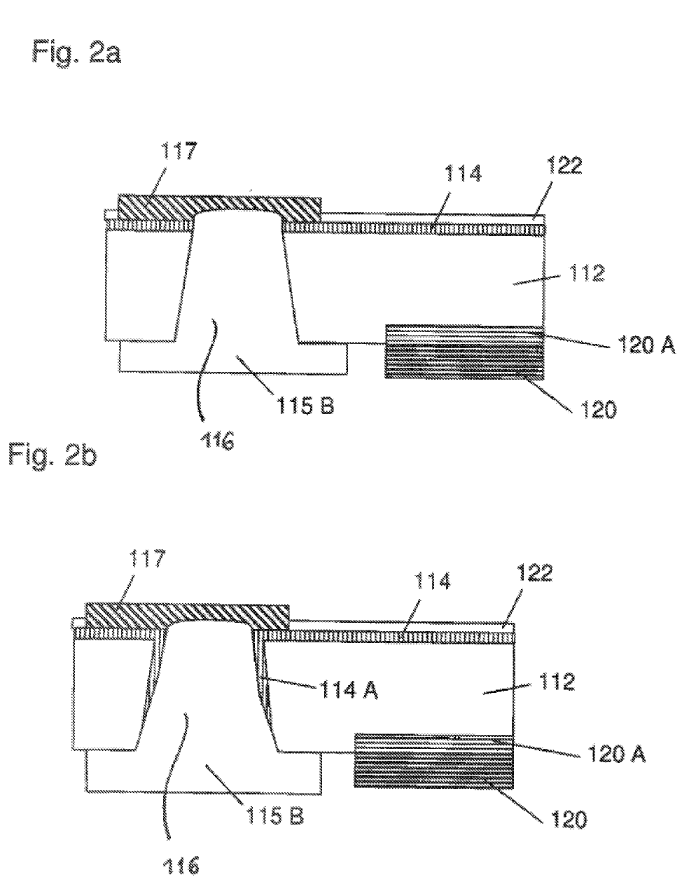

FIGS. 2a, 2b show excerpts of MWT solar cells according to the invention;

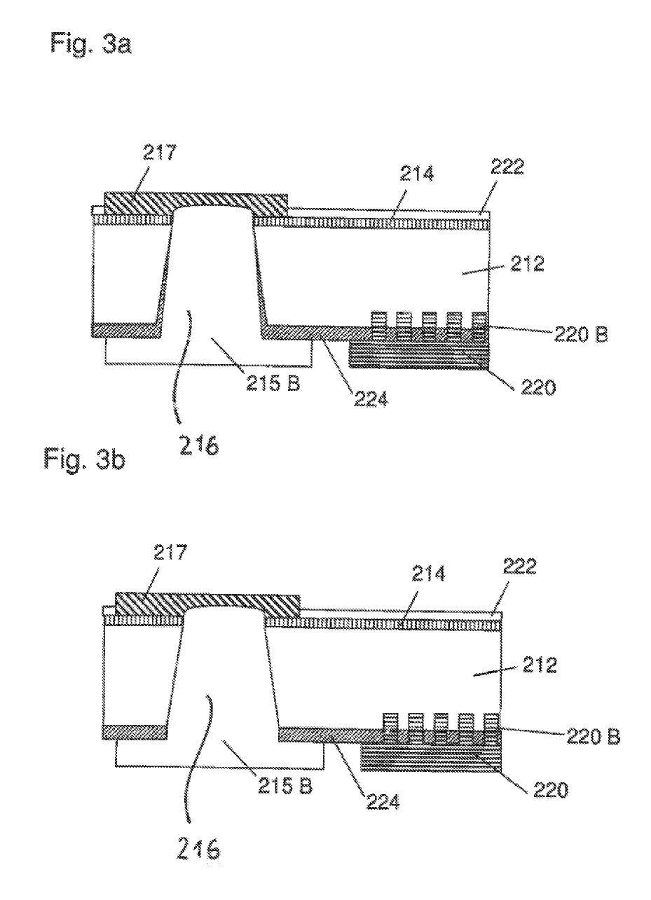

FIGS. 3a, 3b show excerpts of MWT-PERC cells according to the invention;

FIGS. 4a, 4b show flow charts for producing an MWT or MWT-PERC solar cell;

FIG. 5 shows a basic illustration of an MWT-PERC cell with via metallizing, which is isolated relative to the base;

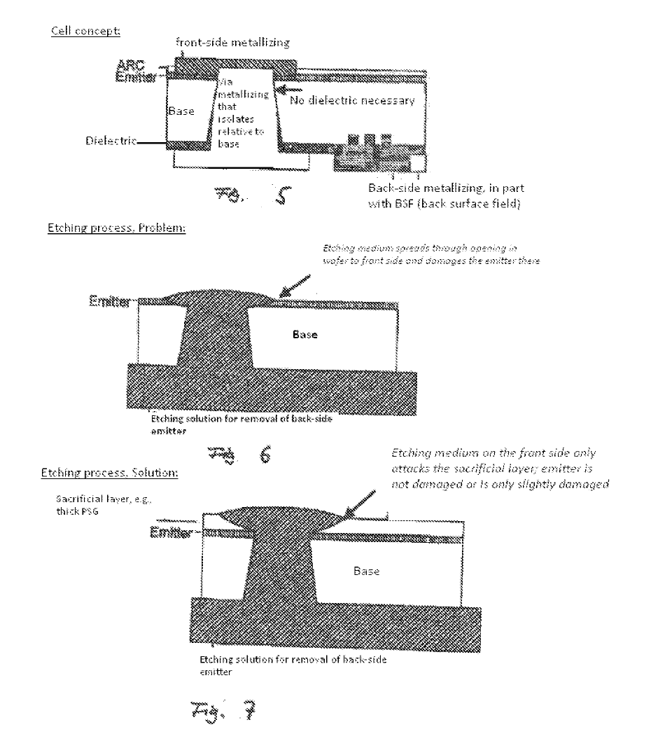

FIG. 6 shows a basic illustration of an MWT solar cell, which is subjected to an etching process on the back side, for the removal of an emitter; and

FIG. 7 shows the basic illustration of an MWT cell having a sacrificial layer according to the invention.

Excerpts of MWT or MWT-PERC solar cells according to the invention are shown in FIGS. 2a, 2b, 3a, 3b, in which the same reference numbers are basically used for the same elements. Further, for reasons of simplification, a p-silicon-based semiconductor material is assumed as the substrate or wafer, and the layers having n-doping are designated as emitters. The following measures apply analogously to other semiconductor materials and conductivities without requiring further explanation.

An MWT cell that can be designated a standard MWT cell, without a dielectric layer running on the back side as in the case of a PERC cell, is shown in the excerpts in FIGS. 2a, 2b.

As described in connection with FIGS. 1a, 1b, according to FIGS. 2a, 2b, passage openings 116 are first formed in the substrate forming the base 112 (p-conducting), e.g., by means of a laser process. A texturing is then provided. An emitter layer 114 is subsequently formed on the front side by means of a phosphorus dopant source, such as gaseous POCl₃ or the liquid H₃PO₄ solution, the layer being formed also on the back side of the base 112 and in the passage openings 116, sometimes with different thickness, brought about by the production process.

Independently of whether a superficial layer is introduced on the front side of the substrate, the PSG (phosphosilicate glass) layer that forms during the diffusion process is removed in a solution containing HF. Then, an anti-reflection layer 122 can be introduced on the front side. Finally, a paste is introduced into the passage openings 116, which seals the passage openings 116, and extends from the front side of the substrate to the back side and along this side, as illustrated in the basic illustration. In this case, the paste has properties so that it acts in an isolating manner opposite the p-conducting substrate 112, i.e., the base, after the hardening or sintering; otherwise the necessary passage metallizing is formed, as is necessary for MWT cells, in order to produce electrically conducting connections from the front-side emitter to the back side. Then, a front-side metallizing 117 that contacts the via paste is introduced in the usual way, and an electrically conducting layer, such as an aluminum layer 120, is applied on the entire surface of the back side outside the contactings with the passage metallizings, so that a back surface field (BSF layer) 120A can form.

As long as the emitter extends through the passage openings 116 and along the back side, corresponding to the example of embodiment of FIGS. 1a, 1b, an electrical isolation of the Al layer 120 from the emitter layer running on the back side is provided by lasering, as has been explained on the basis of FIGS. 1a, 1b.

According to the example of embodiment of FIG. 2a, however, the emitter 114 can be recognized to extend exclusively along the front side of the solar cell. An emitter layer is not present on the back side and in the passage openings 116. This notwithstanding, however, a short circuit between the contact passage to the base, i.e., the p-conducting substrate 112, cannot occur, since the paste introduced into the passage openings 116 after the hardening or sintering acts in an electrically isolating manner opposite the substrate.

In the example of embodiment of FIG. 2b, the emitter extends in sections inside the passage openings 116.

The example of embodiment of FIGS. 3a, 3b, which reproduce an excerpt of a PERC cell, is distinguished from that of FIGS. 2a, 2b effectively in that a dielectric layer 224 runs at least along the back side of the substrate 212. The dielectric layer 224 may involve an oxide, as can be derived from EP-A-2 068 369, the disclosure of which is referenced in detail. The dielectric layer 224, which may also be a layer system, is particularly composed of silicon oxide or aluminum oxide having a silicon nitride cover layer.

The procedure for the method for producing MWT-PERC cells corresponding to FIGS. 3a, 3b can be seen in FIG. 4b. Thus, after introducing the anti-reflection layer 222, the back side is passivated, the layer 224 having been deposited. Then the paste 215b according to the invention will be introduced into the passage openings 216; this paste completely fills the passage openings 216. There is also the possibility, however, that the paste is formed in such a way that a passage opening forms in the central region, i.e., a so-called “bore” is present, as can also be seen in FIG. 1b. Subsequently, the front-side metallizing 217 as well as the back-side metallizing (metal layer 220) is introduced in the usual way, whereby openings in the dielectric layer 224 lead to the formation of local back surface field regions 220B. Heat treatment steps for making possible a sintering are provided for this in the usual way.

Essential aspects of the invention will be explained once more based on FIGS. 5 to 7.

MWT (metal wrap through) solar cells are cells in which the contacting of the front-side metallizing is produced from the back side, so-called back contact cells. In the case of MWT cells, for this purpose, a metal connection is guided from the front side through apertures in the cell onto the back side, as shown in FIG. 5.

PERC (passivated emitter and rear cell) in particular designates the passivation of the back side by means of a dielectric layer. In order to be able to introduce this layer in a useful way, a possibly present back-side emitter needs to be completely removed or removed at least in all regions in which the passivation is intended.

The present invention, among other things, involves the application of the PERC concept to MWT cells.

A previously unresolved problem is based on the fact that in the case of chemical back-etching of the back-side emitter, the front side is connected to the back side through the apertures. Typically, etching medium introduced from the back side also reaches the front side through the apertures. A contact of the etching medium with the front side, particularly in the region of the apertures, therefore cannot be excluded, so that an emitter back-etching also occurs therein, which negatively influences the performance of the cell, as shown in FIG. 6.

MWT technology and PERC technology are established technologies. It is known to introduce into the aperture an isolation layer that prevents a contact to the base. The problem of emitter back-etching onto the back side has not been addressed in the prior art.

In the case of MWT solar cells, a metal contact must pass through an opening in the substrate from the back side to contact the front side. In this case, this metal must not be in electrically conducting contact with the semiconductor base. In standard MWT cells, the base is shielded from the metal contact by the emitter, as shown in FIG. 5.

For a (PERC) solar cell passivated on the back side, however, a possibly present emitter diffusion on the back side must be completely removed outside the contact passage, usually by surface etching.

In a first solution according to the invention, an isolation is produced in the aperture, but this isolation is not based on the coating in the aperture, but rather, e.g., on the electrically isolating property of a paste. Thus for a partially or completely exposed base, in particular, this works even without a coating in the region of the aperture, or with a non-homogeneous coating that does not completely cover all regions of the emitter contact. The isolation is thus achieved according to the invention by an electrically non-contacting paste. In this case, the requirements for isolation in the aperture can be clearly reduced.

In the case of removal of the back-side emitter, a superficial etching of the front side is avoided by means of a suitable protection method, which prevents or reduces the attack of the emitter.

Another solution according to the invention is characterized in that the emitter is protected on the front side and/or in the aperture during back-etching preferably by means of a PSG (phosphosilicate glass) layer of suitable thickness. This can be produced, for example, in a long (i.e., for example, longer than 25 min) (in-line) diffusion process or an oxidation step. A possible superficial etching of the front side and/or the aperture first attacks the PSG sacrificial layer, so that the emitter remains protected for a sufficiently long time, as shown in FIG. 7.

Yet another solution according to the invention is characterized in that the emitter is protected on the front side and/or in the aperture during back-etching by means of another technical variant, so that small quantities of etching solution that pass through the apertures to the front side, do not lead to or only barely lead to an attack of the emitter on the front side and/or in the aperture. This can be carried out, for example, by means of diluting or neutralizing the etching solution by employing a suitable solution introduced on the front side.

The three named variants or solutions, i.e.: an electrically non-contacting, i.e., isolating paste opposite the substrate, this paste, however, assuring the necessary electrical conductivity for the electrically conducting connection between the emitter running on the front side and the back side; the sacrificial layer that is introduced on the front side and is etched away during the etching away of the emitter regions running on the back side; and the possibility of weakening the etching effect of the etching fluid passing through the passage openings, can be combined in any desired combination and additionally can be used independently from one another.

1-12. (canceled)

13. A method for producing a solar cell made of a semiconductor substrate having a front side and a back side, of a first conductivity type, comprising the steps of:
forming several passage openings extending from the front side to the back side;
producing a layer of a conductivity type that is opposite to the first conductivity type at least along the front side by diffusing in a dopant from a dopant source; and
producing an electrically conducting connection between the front side through the passage opening to contact regions adjacent to the passage openings on the back side, wherein the step of producing the electrically conducting connection comprises using a material that forms isolating properties opposite the semiconductor substrate.

14. The method according to claim 13, further comprising using a paste as the material that has the isolating effect opposite the semiconductor substrate, and subjecting the paste to a thermal treatment for the formation of the electrically conducting connection with the simultaneous formation of an isolation layer in the regions contacting the substrate.

15. The method according to claim 13, further comprising wet-chemical etching the back side to provide the first conductivity type.

16. The method according to claim 14, wherein the paste is hardened by the thermal treatment, the hardening being conducted over a time period between 1 and 20 seconds at a substrate temperature of at least 700° C.

17. The method according to claim 16, wherein the thermal treatment is provided in a nitrogen or a nitrogen-oxygen atmosphere.

18. The method according to claim 14, wherein the paste comprises particles selected from the group consisting of glass particles, silver particles, and organic substances.

19. The method according to claim 14, wherein the paste comprises silver particles and up to 80% to 100% of the silver particles are flakes having a D90 size distribution determined by laser diffraction in the range of 1 μm to 20 μm.

20. The method according to claim 14, wherein the paste comprises glass particles having a D90 size distribution determined by laser diffraction in the range of 0.5 μm to 20 μm.

21. The method according to claim 20, wherein the glass particles are lead-free glass and have a glass softening point in the range between 350° C. and 550° C.

22. The method according to claim 14, wherein the paste has a solids fraction in the range between 80 wt. % and 95 wt. %.

23. The method according to claim 14, wherein the paste has a glass fraction that lies in the range between 1 wt. % and 15 wt. %.

24. A solar cell produced according to the method of claim 13.

25. A method for producing an MWT-PERC solar cell, comprising:
defining contact passages through openings in a substrate of the solar cell between a front side and a back side;
completely removing emitter regions that are present on the back side of the solar cell outside the contact passages; and
applying a dielectric layer on the back side, wherein the contact passages comprise a paste that does not act in an electrically contacting manner opposite the substrate.

26. The method according to claim 25, further comprising subjecting the paste to a thermal treatment for the formation of the contact passages with the simultaneous formation of an isolation layer in the regions contacting the substrate.

27. The method according to claim 26, wherein the paste is hardened by the thermal treatment, the hardening being conducted over a time period between 1 and 20 seconds at a substrate temperature of at least 700° C.

28. The method according to claim 27, wherein the thermal treatment is provided in a nitrogen or a nitrogen-oxygen atmosphere.

29. The method according to claim 25, wherein the paste comprises particles selected from the group consisting of glass particles, silver particles, and organic substances.

30. The method according to claim 25, wherein the paste has a solids fraction in the range between 80 wt. % and 95 wt. %.

31. The method according to claim 25, wherein the paste has a glass fraction that lies in the range between 1 wt. % and 15 wt. %.

32. A solar cell produced according to the method of claim 25.
